(19) United States
(12) Patent Application Publication
(10) Pub. No.: US 2013/0019947 A1
(43) Pub. Date: Jan. 24, 2013

(54) PHOTOELECTRIC CONVERSION ELEMENT MODULE AND ARCHITECTURAL STRUCTURE

(71) Applicants: Kazuyuki Ejima, Kanagawa (JP); Akira Ono, Kanagawa (JP); Keigo Sugimoto, Kanagawa (JP)

(72) Inventors: Kazuyuki Ejima, Kanagawa (JP); Akira Ono, Kanagawa (JP); Keigo Sugimoto, Kanagawa (JP)

(73) Assignee: Sony Corporation, Tokyo (JP)

(21) Appl. No.: 13/545,728

(22) Filed: Jul. 10, 2012

(30) Foreign Application Priority Data
Jul. 21, 2011 (JP) 2011-159793

(51) Int. Cl. H01L 31/0203

(52) U.S. Cl. 136/259

(57) ABSTRACT

A photoelectric conversion element module includes a first base material, a second base material, a photoelectric conversion element having a light incident side and sealing portion and arranged between the first and second base materials, an anchoring layer adapted to anchor one of main sides of a light incident side and a side opposite to the light incident side, and one of a main side of the first and second base material opposed to one of the main sides, and a covering section adapted to cover the sealing portion. The Young's modulus of the covering section is 0 MPa or more and 20 MPa or less.

### BACKGROUND

The present technology relates to a photoelectric conversion element module and architectural structure and, more particularly, to a photoelectric conversion element module housing one or more photoelectric conversion elements in a housing body and an architectural structure using the same.

Among types of solar cells known in the past are crystalline solar cells, amorphous, compound semiconductor, thin film polycrystalline and organic solar cells. Recent years have seen attention focused on a dye sensitized solar cell as a potential substitute with low manufacturing cost for the above types of solar cells. This cell has a photoelectric conversion activating substance layer in which semiconductor particles hold a dye adapted to absorb visible light.

A solar cell may use a cell element module made up of a large number of cell elements connected together for a larger power generation area. As such a cell element module, one having two sheets of plate glass is, for example, known. A sealant sheet is provided on the surface of each of the sheets of plate glass. The sides of these sheets of plate glass each having the sealant sheet are arranged to be opposed to each other. With cell elements lying between the two sealant sheets, the cell elements are laminated (refer, for example, to Japanese Patent Laid-Open No. 2007-294869). Also known is a cell element module having, in place of either or both of the two sheets of plate glass, resin substrates or sheets of resin film.

### SUMMARY

In a cell element module having a laminated structure, however, an external force exerted on the cell element module propagates to the cell elements through the sealant, thus causing the external force to be also exerted on the cell elements. Unlike crystalline solar cells, a dye sensitized solar cell is commonly a structure having an electrolytic solution sealed therein. As a result, an external force exerted on the cell element module may damage the sealing structure of the dye sensitized solar cell in the cell element module.

In light of the foregoing, it is desirable to provide a photoelectric conversion element module and architectural structure with minimal possible damage to the sealing structure of the dye sensitized solar cell.

According to an embodiment of the present technology, there is provided a photoelectric conversion element module including first and second base materials, a photoelectric conversion element, anchoring layer and covering section. The photoelectric conversion element has a light incident side and sealing portion and is arranged between the first and second base materials. The anchoring layer anchors one of main sides of a light incident side and a side opposite to the light incident side, and one of main sides of the first and second base material opposed to one of the main sides. The covering section covers the sealing portion. The Young's modulus of the covering section is 0 MPa or more and 20 MPa or less.

In the present technology, the photoelectric conversion element module is suitable for use in an architectural structure. Further, the photoelectric conversion element module is suitable for use, for example, in an architectural structure having a light collection section. Still further, the photoelectric conversion element module is suitable for use as a construction member such as a window material (e.g., window glass) and curtain wall. As a window material, eco-friendly glass such as multi-layered glass, laminated glass, Low-E glass or Low-E multi-layered glass is preferred. If the photoelectric conversion element module is applied to such eco-friendly glass, the first base material should preferably be a first glass plate, and the second base material a second glass plate. The photoelectric conversion element module may include a sealant between the peripheral portions of the first and second base materials.

In the present technology, the photoelectric conversion element should preferably have an incident side on which light falls, a main side opposite to the incident side, and a lateral side provided between the peripheral portions of the incident and main sides, with a sealing portion provided on the peripheral portion of the incident side, that of the main side or the lateral side.

In the present technology, only one of transparent and opposed base materials making up the sealing structure of the photoelectric conversion element should preferably be anchored to an inner side of a housing body. The reason for this is that an external force exerted on the photoelectric conversion element module does not directly propagate to both of the transparent and opposed base materials through the medium of the anchoring layer, thus suppressing the cleavage of the sealing structure of the photoelectric conversion element.

In the present technology, the sealing portion of the photoelectric conversion element is covered with the covering section, thus reinforcing the sealing portion. Further, it is possible to suppress the entry of moisture into the photoelectric conversion element from the sealing portion. Still further, the covering section is made of a soft material. As a result, the covering section serves as a cushioning material, thus suppressing the cleavage of the sealing structure of the photoelectric conversion element even in the event that an external force may be exerted on the photoelectric conversion element module or stress caused by moisture absorption or thermal expansion may be generated.

As described above, the present technology provides a photoelectric conversion element module and architectural structure with minimal possible damage to the sealing structure of the dye sensitized solar cell.

### BRIEF DESCRIPTION OF THE DRAWINGS

FIG. 1A is a plan view illustrating a configuration example of a photoelectric conversion element module according to a first embodiment of the present technology, FIG. 1B is a cross-sectional view along line I-I in FIG. 1A, and FIG. 1C is a cross-sectional view showing a photoelectric conversion element in an enlarged manner;

FIG. 2A is a cross-sectional view illustrating a configuration example of the photoelectric conversion element, and FIG. 2B is a cross-sectional view illustrating an example of positional relationship between a sealing portion of the photoelectric conversion element and the surface of a covering section;

FIGS. 3A to 3C are cross-sectional views illustrating configuration examples of positional relationship between the sealing portion of the photoelectric conversion element and the surface of the covering section;

FIGS. 4A to 4D are process diagrams illustrating examples of manufacturing steps of the photoelectric conversion element module according to the first embodiment of the present technology;

FIG. 5A is a cross-sectional view illustrating a first modification example of the photoelectric conversion element module according to the first embodiment of the present technology, and FIG. 5B is a cross-sectional view illustrating a second modification example of the photoelectric conversion element module according to the first embodiment of the present technology;

FIG. 6A is a plan view illustrating a third modification example of the photoelectric conversion element module according to the first embodiment of the present technology, FIG. 6B is a cross-sectional view along line VI-VI in FIG. 6A, and FIG. 6C is a cross-sectional view illustrating a fourth modification example of the photoelectric conversion element module according to the first embodiment of the present technology;

FIG. 7A is a plan view illustrating a configuration example of a photoelectric conversion element module according to a second embodiment of the present technology, FIG. 7B is a cross-sectional view along line VII-VII in FIG. 7A, and FIG. 7C is a cross-sectional view illustrating a first modification example of the photoelectric conversion element module according to the second embodiment of the present technology;

FIG. 8A is a plan view illustrating a second modification example of the photoelectric conversion element module according to the second embodiment of the present technology, and FIG. 8B is a cross-sectional view along line VIII-VIII in FIG. 8A;

FIG. 9A is a cross-sectional view illustrating a configuration example of a photoelectric conversion element module according to a third embodiment of the present technology, and FIG. 9B is a cross-sectional view illustrating a first modification example of the photoelectric conversion element module according to the third embodiment of the present technology;

FIGS. 10A to 10C are diagrams illustrating examples of architectural structures according to the present technology; and

FIG. 11A is a cross-sectional view illustrating a configuration example in which only an opposed base material of the photoelectric conversion element is anchored to the inner side of a housing body with an anchoring layer, and FIG. 11B is a cross-sectional view illustrating a configuration example in which only a transparent base material of the photoelectric conversion element is anchored to the inner side of the housing body with the anchoring layer.

### DETAILED DESCRIPTION OF THE PREFERRED EMBODIMENTS

A description will be given below of the preferred embodiments of the present technology in the following order:

1. First Embodiment (example in which the rear side of a photoelectric conversion element is anchored with an anchoring layer)

2. Second Embodiment (example in which the incident side of a photoelectric conversion element is anchored with an anchoring layer)

3. Third Embodiment (example in which a photoelectric conversion element is supported by a covering section)

4. Fourth Embodiment (example in which an architectural structure includes a photoelectric conversion element module)

### 1. First Embodiment

### Configuration of Photoelectric Conversion Element Module

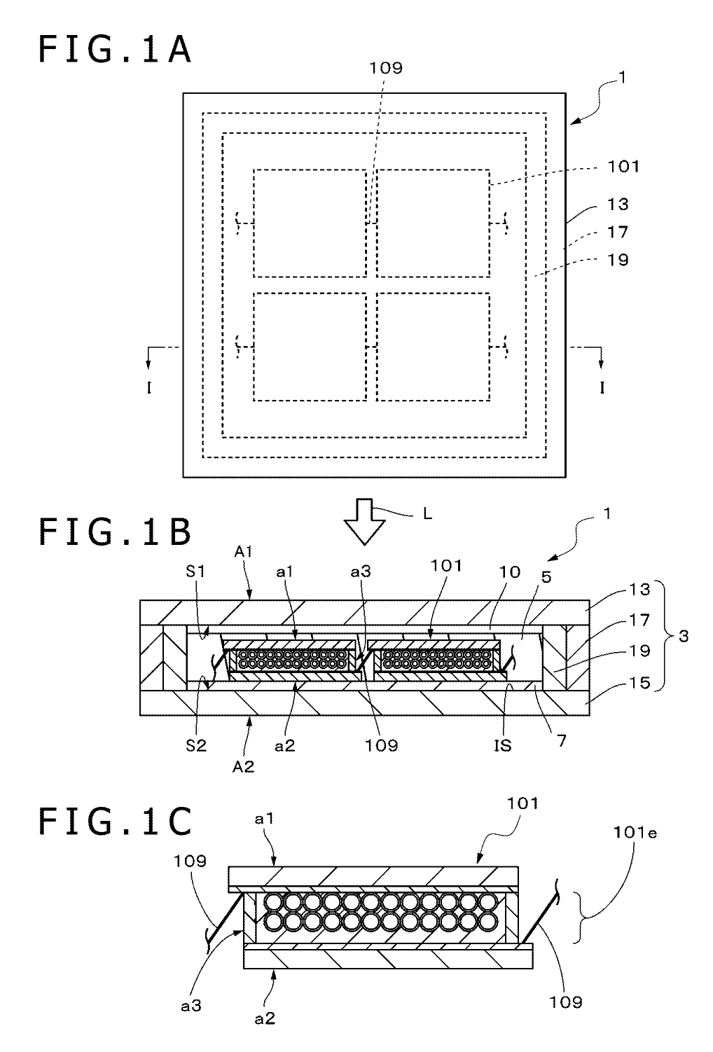

FIG. 1A is a plan view illustrating a configuration example of a photoelectric conversion element module according to a first embodiment of the present technology. FIG. 1B is a cross-sectional view along line I-I in FIG. 1A. FIG. 1C is a cross-sectional view showing a photoelectric conversion element in FIG. 1B in an enlarged manner. As illustrated in FIGS. 1A and 1B, a photoelectric conversion element module 1 according to the first embodiment includes at least one photoelectric conversion element 101, first and second base materials 13 and 15, covering section 5 and anchoring layer 7. The photoelectric conversion element 101 has a light incident side and sealing portion. The first and second base materials 13 and 15 make up a housing space IS adapted to house the photoelectric conversion element 101. The covering section 5 covers the sealing portion of the photoelectric conversion element 101. The anchoring layer 7 anchors the position of the photoelectric conversion element 101 in a housing body 3. The photoelectric conversion elements 101 are electrically connected together if there are two or more thereof. In the present technology, the Young's modulus of the covering section 5 is 0 MPa or more and 20 MPa or less. This photoelectric conversion element module 1 is so called a dye sensitized photoelectric conversion element module to convert incident light L such as sunlight into electric energy and supply this energy to external equipment as electric power. The photoelectric conversion element module 1 has two sides, an incident side A1 on which the incident light L such as sunlight falls, and a rear side A2 opposite to the incident side A1.

As illustrated in FIGS. 1B and 1C, the photoelectric conversion element 101 has an incident side a1, rear side a2 and lateral side a3. The incident light L such as sunlight falls on the incident side a1. The rear side a2 is opposite to the incident side a1. The lateral side a3 is provided between the incident side a1 and rear side a2. The plurality of photoelectric conversion elements 101 are electrically connected together in series and/or in parallel by a plurality of wirings (connection members) 109, thus supplying electric power generated by each of the plurality of photoelectric conversion elements 101 to equipment external to the photoelectric conversion element module 1 via the plurality of wirings 109. Although an example is shown in FIGS. 1A and 1B in which the four photoelectric conversion elements 101 are housed in the housing body 3 which will be described later, the number of the photoelectric conversion elements 101 is not limited to this example.

The housing body 3 has the housing space IS adapted to house the photoelectric conversion element 101. The housing space IS is formed by a first inner side S1 and second inner side S2. The first inner side S1 is opposed to the incident side a1 of the photoelectric conversion element 101. The second inner side S2 is opposed to the rear side a2 of the photoelectric conversion element 101. For example, the anchoring layer 7 lies between the second inner side S2 of the housing body 3 and the rear side a2 of the photoelectric conversion element 101, and the photoelectric conversion element 101 is anchored to the second inner side S2 of the housing body 3 by the anchoring layer 7. It should be noted that although FIG. 1B illustrates an example in which the anchoring layer 7 is provided over the entire surface of the rear side a2 of the photoelectric conversion element 101, the anchoring layer 7 may be provided over at least part of the surface of the rear side a2 of the photoelectric conversion element 101.

A sealing portion 101e of the photoelectric conversion element 101 is covered with the covering section 5. That is, the plurality of photoelectric conversion elements 101, anchoring layer 7 and covering section 5 are arranged in the housing space IS in the configuration example shown in FIG. 1B. The covering section 5 is, for example, formed to have a height extending from the rear side a2 of the photoelectric conversion element 101 to at least the incident side a1 of the photoelectric conversion element 101, thus covering a sealing portion 101e of the photoelectric conversion element 101. It should be noted that although FIG. 1B illustrates a configuration example in which a hollow layer 10 having a given width is formed between the covering section 5 and the first inner side S1 of the housing space IS, the configuration of the photoelectric conversion element 101 is not limited to this example. Of course, the covering section 5 may be formed to fill the space extending from the rear side a2 of the photoelectric conversion element 101 to the first inner side S1 of the housing space IS. Alternatively, the incident side a1 of the photoelectric conversion element 101 may be left open to the first inner side S1 of the housing body 3.

### (Photoelectric Conversion Element)

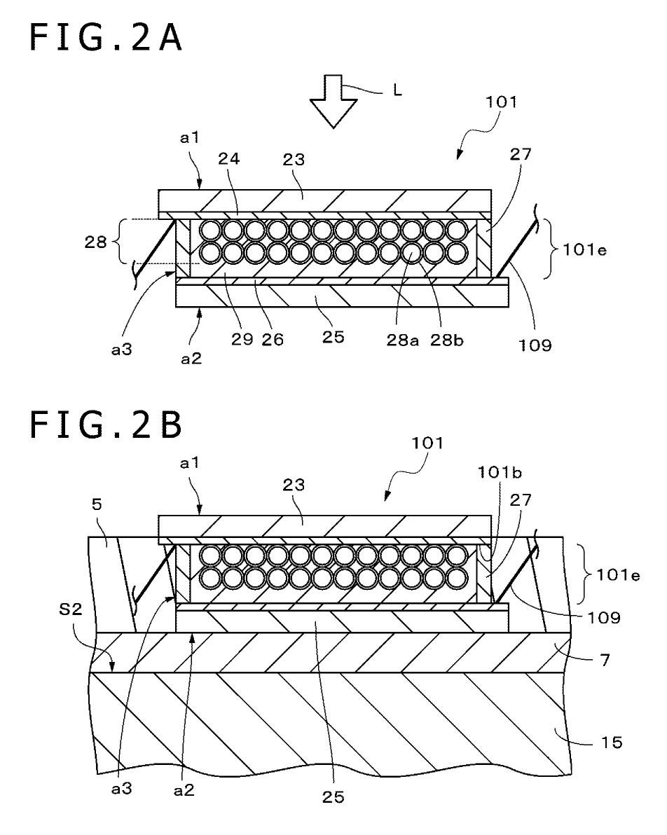

FIG. 2A is a cross-sectional view illustrating a configuration example of the photoelectric conversion element. The photoelectric conversion element 101 is a so-called dye sensitized photoelectric conversion element which includes a transparent base material 23, transparent electrode 24, opposed base material 25, opposed electrode 26, sealant 27, porous semiconductor layer 28 and electrolyte layer 29 as illustrated in FIG. 2A. Here, the transparent electrode 24, porous semiconductor layer 28, electrolyte layer 29 and opposed electrode 26 form a power generating element section. This power generating element section is provided between the transparent base material 23 and opposed base material 25. Of course, the transparent electrode 24, porous semiconductor layer 28 and opposed electrode 26 may be patterned so that the single photoelectric conversion element 101 has the plurality of power generating element sections that are electrically connected to each other. The term “photoelectric conversion element” in the present technology includes that which has a plurality of power generating element sections that are electrically connected to each other. On the other hand, the term “module” refers to that which has a plurality of photoelectric conversion elements that are electrically connected to each other. It should be noted that although FIG. 2A illustrates a so-called opposed cell structure as an example, a monolithic or Z-shaped cell structure is also applicable to the photoelectric conversion element according to the present technology.

The opposed base material 25 is provided to be opposed to the transparent base material 23. The same material 23 has a main side opposed to the opposed base material 25. The transparent electrode 24 is formed on this main side, and the porous semiconductor layer 28 is formed on the surface of the transparent electrode 24. The opposed base material 25 has a main side opposed to the transparent base material 23. The opposed electrode 26 is formed on this main side. The electrolyte layer 29 lies between the porous semiconductor layer 28 and opposed electrode 26 that are arranged to be opposed to each other.

The sealant 27 is provided on the peripheral portions of the opposed sides of the transparent base material 23 and opposed base material 25. The clearance between the porous semiconductor layer 28 and opposed electrode 26 should preferably be 0 to 100 μm, and more preferably 1 to 40 μm. The electrolyte layer 29 is sealed in a space surrounded by three components, firstly, the transparent base material 23 on which the transparent electrode 24 and porous semiconductor layer 28 are formed, secondly, the opposed base material 25 on which the opposed electrode 26 is formed, and thirdly, the sealant 27.

### [Transparent Base Material]

A material that can be used as the transparent base material 23 is not specifically limited so long as it is transparent, and a variety of base materials can be used as the transparent base material 23. For example, a transparent inorganic or plastic base material can be used. Of all these materials, a transparent plastic material is preferred in consideration of workability and lightweight. As for the shape of the base material, a transparent film, sheet, substrate and so on can be used. A material having not only excellent capability to shut off outside moisture and gases which would otherwise find their way into the photoelectric conversion element 101 but also excellent solvent resistance, weather resistance and other characteristics is preferred. Among inorganic base materials having such characteristics are quartz, sapphire and glass. Among plastic base materials having such characteristics are well-known polymer materials. More specifically, among well-known polymer materials are triacetyl cellulose (TAC), polyester (TPEE), polyethylene terephthalate (PET), polyethylene naphthalate (PEN), polyimide (PI), polyamide (PA), amide, polyethylene (PE), polyacrylate, polyether sulfone, polysulfone, polypropylene (PP), diacetyl cellulose, polyvinyl chloride, acrylic resin (PMMA), polycarbonate (PC), epoxy resin, urea resin, urethane resin, melamine resin and cycloolefin polymer (COP). Of all these inorganic and plastic base materials, that having high transmittance in the visible region is particularly preferred. However, a material that can be used as the transparent base material 23 is not limited thereto.

### [Transparent Electrode]

The transparent electrode 24 should preferably offer low light absorption in the visible to near infrared regions of sunlight. A transparent conductive material can be used as the transparent electrode 24. A metal oxide having excellent conductivity or carbon, for example, is preferred for use as a transparent conductive material. For example, one or more selected, for example, from a group of indium-tin composite oxide (ITO), fluorine-doped SnO₂ (FTO), antimony-doped SnO₂ (ATO), tin oxide (SnO₂), zinc oxide (ZnO), indium-zinc composite oxide (IZO), aluminum-zinc composite oxide (AZO) and gallium-zinc composite oxide (GZO) can be used as a metal oxide. A layer intended to promote binding, provide improved electron transfer or prevent reverse electron process may be further provided between the transparent electrode 24 and porous semiconductor layer 28.

### [Opposed Base Material]

A material that can be used as the opposed base material 25 is not specifically limited to being transparent. Instead, an opaque material can also be used. For example, a variety of base materials including opaque or transparent inorganic or plastic base materials can be used. Although any of the materials given above as examples for the transparent base material 23 may be similarly used as an inorganic or plastic base material, opaque base materials such as metallic ones may also be used in addition to the above.

### [Opposed Electrode]

The opposed electrode 26 serves as a cathode of the photoelectric conversion element 101. Among conductive materials for use as the opposed electrode 26 are metals, metal oxides and carbon. However, a material that can be used as the opposed electrode 26 is not limited thereto. Among metals that can be used as the opposed electrode 26 are platinum, gold, silver, copper, aluminum, rhodium and indium. However, the metal for use as the opposed electrode 26 is not limited thereto. Among metal oxides that can be used as the opposed electrode 26 are ITO (indium-tin oxide), tin oxide (including, for example, fluorine-doped tin oxides) and zinc oxide. However, the metal oxide for use as the opposed electrode 26 is not limited thereto. Although not specifically limited, the thickness of the opposed electrode 26 should preferably be 5 nm or more and 100 μm or less.

### [Sealant]

Thermoplastic and photosetting resins and glass frit can be, for example, used as the sealant 27. However, a material that can be used as the sealant 27 is not limited thereto.

### [Porous Semiconductor Layer]

The porous semiconductor layer 28 should preferably be a porous layer including metal oxide semiconductor fine particles 28a. The metal oxide semiconductor fine particles 28a should preferably hold a sensitizing dye 28b on their surface. The metal oxide semiconductor fine particles 28a should preferably include a metal oxide containing at least one of titanium, zinc, tin and niobium. More specifically, one or more selected from a group of titanium oxide, tin oxide, tungsten oxide, zinc oxide, indium oxide, niobium oxide, iron oxide, nickel oxide, cobalt oxide, strontium oxide, tantalum oxide, antimony oxide, lanthanoid oxide, yttrium oxide, vanadium oxide and so on can be used as the metal oxide semiconductor fine particles 28a. However, a material that can be used as the metal oxide semiconductor fine particles 28a is not limited thereto. In order for the surface of the porous semiconductor layer to be sensitized by the sensitizing dye 28b, the conduction band of the porous semiconductor layer 28 should be located where electrons can be readily gained from the photoexcitation level of the sensitizing dye 28b. From this point of view, it is particularly preferred to select one or more from a group of titanium oxide, zinc oxide, tin oxide and niobium oxide of all the materials given above for use as the metal oxide semiconductor fine particles 28a. Further, titanium oxide is most preferred from the viewpoint of price and environmental hygiene. It is particularly preferred that the metal oxide semiconductor fine particles 28a should contain titanium oxide having an anatase or brookite crystal structure. The mean primary particle diameter of the metal oxide semiconductor fine particles 28a should preferably be 5 nm or more and 500 nm or less. A mean primary particle diameter smaller than 5 nm tends to lead to degraded crystallinity, making it difficult to maintain an anatase structure and resulting in an amorphous structure. On the other hand, a mean primary particle diameter greater than 500 nm tends to lead to reduced specific surface area, resulting in a reduced total amount of the sensitizing dye 28b adsorbed to the porous semiconductor layer 28 for contribution to power generation.

### [Sensitizing Dye]

A material that can be used as the sensitizing dye 28b for photoelectric conversion is not specifically limited so long as it has sensitizing effect. However, a substance capable of absorbing light in and near the visible region is commonly used such as bipyridine complex, terpyridine complex, merocyanine dye, porphyrin or phthalocyanine.

As the sensitizing dye 28b to be used alone, cis-bis(isothiocyanato)bis(2,2′-bipyridyl-4,4′-dicarboxylic acid)-ruthenium(II)bis-tetrabutylammonium complex, i.e., a kind of bipyridine complex (commonly known as N719), is generally used for its excellent performance. In addition to the above, cis-bis(isothiocyanato)bis(2,2′-bipyridyl-4,4′-dicarboxylic acid)-ruthenium(II), i.e., a kind of bipyridine complex (commonly known as N3), and tris(isothiocyanato)(2,2′:6′,2″-terpyridyl-4,4′,4″-tricarboxylic acid)-ruthenium(II)tris-tetrabutylammonium complex, i.e., a kind of terpyridine complex (commonly known as black dye) are generally used.

In particular, when the N3 or black dye is used, a coabsorbent is also often used. A coabsorbent is a molecule added to prevent the association of dye molecules on the porous semiconductor layer 28. Among typical coabsorbents are chenodeoxycholic acid, taurodeoxycholic acid and 1-decryl phosphonic acid. These molecules offer such structural characteristics as having a carboxyl or phosphono group as a functional group readily adsorbed to titanium oxide making up the porous semiconductor layer 28 and being formed by sigma bond so as to lie between the dye molecules and prevent the interference therebetween.

Among other dyes for use as the sensitizing dye 28b are azo-based dyes, quinacridone-based dyes, diketopyrrolopyrrole-based dyes, squarilium-based dyes, cyanine-based dyes, merocyanine-based dyes, triphenylmethane-based dyes, xanthene-based dyes, porphine-based dyes, chlorophyll-based dyes, ruthenium complex-based dyes, indigo-based dyes, perylene-based dyes, oxazine-based dyes, anthraquinone-based dyes, phthalocyanine-based dyes and naphthalocyanine-based dyes and their derivatives. However, the dye for use as the sensitizing dye 28b is not limited thereto so long as it is capable of absorbing light and injecting excited electrons into the conduction band of the porous semiconductor layer 28. It is preferred that these dyes for use as the sensitizing dye 28b should have one or more linkage groups in their structure because if so, the dyes can be linked to the surface of the porous semiconductor layer surface, thus making it possible to speedily transfer excited electrons of the photo-excited sensitizing dye 28b to the conduction band of the porous semiconductor layer 28.

The thickness of the porous semiconductor layer 28 should preferably be 0.5 μm or more and 200 μm or less. A thickness smaller than 0.5 μm tends to lead to failure to provide an effective conversion efficiency. On the other hand, a thickness greater than 200 μm tends to lead to difficulties in manufacture such as cracking and peeling during the formation. Further, a thickness greater than 200 μm leads to a greater distance between the surface of the porous semiconductor layer 28 on the side of the electrolyte layer and the surface of the porous semiconductor layer 28 on the side of the transparent electrode. As a result, it becomes difficult to transfer generated electric charge to the transparent electrode 24, thus resulting in reduced tendency to achieve excellent conversion efficiency.

### [Electrolyte Layer]

The electrolyte layer 29 should preferably be made of an electrolyte, medium and additive. Among electrolytes that can be used are mixtures of I₂ and iodide (e.g., LiI, NaI, KI, CsI, MgI₂, CaI₂, CuI, tetraalkyl ammonium iodide, pyridium iodide and imidazolium iodide) and mixtures of Br₂ and bromide (e.g., LiBr). Of these, the electrolytes obtained by mixing I₂ and iodide as mixtures of I₂ and iodide such as LiI, pyridium iodide and imidazolium iodide as mixtures of I₂ and iodide are preferred. However, the combination thereof is not limited to the above.

The concentration of the electrolyte in the medium should preferably be 0.05 to 10 M, and more preferably 0.05 to 5 M, and even more preferably 0.2 to 3 M. The concentration of I₂ and Br₂ should preferably be 0.0005 to 1 M, and more preferably 0.001 to 0.5 M, and even more preferably 0.001 to 0.3 M. On the other hand, a variety of additives such as 4-tert-butylpyridine and benzimidazoliums may be added to provide improved open circuit voltage of the photoelectric conversion element 101.

The medium used as the electrolyte layer 29 should preferably be a compound that can provide excellent ionic conductivity. Among media in a liquid form that can be used as the electrolyte layer 29 are ether compounds such as dioxane and diethyl ether, chain ethers such as ethylene glycol dialkyl ether, propylene glycol dialkyl ether, polyethylene glycol dialkyl ether and polypropylene glycol dialkyl ether, alcohols such as methanol, ethanol, ethylene glycol monoalkyl ether, propylene glycol monoalkyl ether, polyethylene glycol monoalkyl ether and polypropylene glycol monoalkyl ether, polyvalent alcohols such as ethylene glycol, propylene glycol, polyethylene glycol, polypropylene glycol and glycerin, nitrile compounds such as acetonitrile, glutarodinitrile, methoxyacetonitrile, propionitrile and benzonitrile, carbonate compounds such as ethylene carbonate and propylene carbonate, heterocyclic compounds such as 3-methyl-2-oxazolidinone, and aprotic polar substances such as dimethyl sulfoxide and sulfolane.

Further, the electrolyte layer 29 may contain a polymer to use a medium in a solid form (including gel form). In this case, a polymer such as polyacrylonitrile or polyvinylidene fluoride is added to the medium in a solution form, thus polymerizing a multi-functional monomer having an ethylene unsaturated group in the medium in a solution form and transforming the medium into a solid form.

In addition to the above, electrolytes for which CuI or CuSCN medium is not necessary and hole transporting materials such as 2,2′,7,7′-tetrakis(N,N-di-p-methoxyphenylamine)9,9′-spirobifluorene may be used as the electrolyte layer 29.

### (Housing Body)

The housing body 3 includes, for example, the first and second base materials 13 and 15. The housing body 3 may include a sealant 17 and further include a shielding material 19 as necessary. The housing body 3 having a hermetically sealed structure is preferred because this can suppress, for example, the entry of outside moisture. It should be noted that the housing body 3 is inexpensive if it does not have the sealant 17 or shielding material 19.

The first base material 13 has the first inner side S1 opposed to the second base material 15, and the second base material 15 has the second inner side S2 opposed to the first base material 13. The first and second base materials 13 and 15 are arranged to be opposed to each other in such a manner that the first and second inner sides S1 and S2 are spaced from each other, thus forming the housing space IS adapted to house the photoelectric conversion element 101. If the sealant 17 is provided between the peripheral portions of the first and second inner sides S1 and S2, the housing space IS adapted to house the photoelectric conversion element 101 is formed by the first and second base materials 13 and 15 and sealant 17.

### [First Base Material]

A material that can be used as the first base material 13 is not specifically limited so long as it is transparent, and a variety of materials can be used as the first base material 13. For example, a transparent inorganic or plastic base material can be used. Of all these materials, a transparent plastic material is preferred in consideration of workability and lightweight. As for the shape of the first base material 13, a transparent film, sheet, substrate and so on can be used. A material having not only excellent capability to shut off outside moisture and gases which would otherwise find their way into the photoelectric conversion element module 1 but also excellent solvent resistance, weather resistance and other characteristics is preferred. Among inorganic materials having such characteristics are quartz, sapphire and glass. Among plastic materials having such characteristics are well-known polymer materials. More specifically, among well-known polymer materials are triacetyl cellulose (TAC), polyester (TPEE), polyethylene terephthalate (PET), polyethylene naphthalate (PEN), polyimide (PI), polyamide (PA), aramid, polyethylene (PE), polyacrylate, polyether sulfone, polysulfone, polypropylene (PP), diacetyl cellulose, polyvinyl chloride, acrylic resin (PMMA), polycarbonate (PC), epoxy resin, urea resin, urethane resin, melamine resin and cycloolefin polymer (COP). Of all these inorganic and plastic materials, that having high transmittance in the visible region is particularly preferred. However, a material that can be used as the first base material 13 is not limited thereto. If the photoelectric conversion element module is used as a construction member such as a window material, the first base material 13 should preferably be made of a glass plate.

### [Second Base Material]

A material that can be used as the second base material 15 is not specifically limited to being transparent. Instead, an opaque material can also be used. For example, a variety of base materials including opaque or transparent inorganic or plastic base materials can be used. Although any of the materials given above as examples for the first base material 13 may be similarly used as an inorganic or plastic base material, opaque base materials such as metallic ones may also be used in addition to the above. If the photoelectric conversion element module is used as a construction member such as a window material, the second base material 15 should preferably be made of a glass plate.

### [Sealant]

The sealant 17 contains, for example, an adhesive or agglutinant as a main ingredient. If an adhesive is used, the sealant 17 contains one or more adhesives selected, for example, from a group of thermoplastic, thermosetting, room-temperature-setting and energy ray-setting adhesives as main ingredients and may further contain, as necessary, an additive. If an adhesive is used, polysulfide is preferred from the viewpoint of bonding strength. If an agglutinant is used, the sealant 17 contains one or more agglutinants selected, for example, from a group of acrylic, rubber-based and silicon-based agglutinants as main ingredients and may further contain, as necessary, an additive such as crosslinking agent.

### [Shielding Material]

The shielding material 19 is provided, for example, between the peripheral portions of the first inner side S1 of the first base material 13 and the second inner side S2 of the second base material 15. The shielding material 19 is provided on the inner side of the sealant 17 (on the side of the housing space IS) in such a manner as to be adjacent to or spaced from the sealant 17. A material capable of preventing or suppressing the leakage of the material housed in the housing space IS and/or the entry of moisture such as steam from the outside environment into the housing space IS is preferred for use as the shielding material 19. As such a material, shielding materials offering low steam permeability such as polyolefin and polyisobutylene and metallic spacer incorporating a dry material may be used alone or in combination.

### (Covering Section)

The covering section 5 contains, for example, a resin material, synthetic or natural rubber as a main ingredient and may further contain a plasticizer, age resistor, softner, filler or crosslinking agent as an additive. If the covering section 5 lies between the incident side a1 of the photoelectric conversion element 101 and the first inner side S1 of the housing body 3, the same section 5 should preferably be transparent. The covering section 5 may include fine particles as necessary. Among fine particles that can be used are organic and inorganic fine particles.

Among resin materials are silicone (organopolysiloxane)-based resin, modified silicone (polyether having a silyl group at the terminal)-based resin, urethane-based resin, polysulfide-based resin, modified polysulfide-based resin, telechelic polyacrylate-based resin, acrylic resin, acrylic urethane-based resin, vinyl acetate-based resin such as polyvinyl acetate or ethylene-vinyl acetate copolymer, acrylonitrile, hydrocarbon resin, alkylphenol resin, rosin-based resin such as rosin, rosin triglyceride or hydrogenated rosin, and polyvinyl ether. Among synthetic rubbers are butyl rubber, polyisoprene, polyisobutylene, polychloroprene and styrene-butadiene copolymer resin.

A material that can be used as the covering section 5 is not limited to those given above. Instead, a non-setting oil-base caulking may be used as the covering section 5. If possible, two or more of the above materials may be used in combination. It should be noted that if the photoelectric conversion element module 1 is flexible thanks, for example, to the flexible second base material 15, it is preferred to use a low-modulus material as the covering section 5 to ensure that the same section 5 can respond more or less to the flexibility of the second base material 15. Alternatively, the covering section 5 may be in a gel form.

It should be noted that if polyurethane-based material is selected for use as the covering section 5, it is preferred to provide an ultraviolet reflection or absorption layer on the surface of the side of the covering section 5 on which the incident light L falls so as to protect the covering section 5 from ultraviolet rays. At this time, it is preferred that the incident side a1 of the photoelectric conversion element 101 should be left open to the first inner side S1 of the housing body 3 without being covered with the covering section 5 so as to prevent the reduction in conversion efficiency of the photoelectric conversion element 101.

The Young's modulus (also referred to as tensile elastic modulus or longitudinal elastic modulus) of the covering section 5 should preferably be 0 MPa or more and 20 MPa or less, and more preferably 0 MPa or more and 10 MPa or less. One reason for this is that, even in the event that an external force may be exerted on the photoelectric conversion element module 1, a Young's modulus of 20 MPa or less ensures relaxation of the stress propagating to the photoelectric conversion element 101 by the covering section 5, thus suppressing possible damage to the sealing structure of the photoelectric conversion element 101. Another reason for this is that a Young's modulus of 10 MPa or less ensures further relaxation of the stress propagating to the photoelectric conversion element 101.

Here, the Young's modulus of the covering section 5 was measured in an environment of 25° C. as per JIS K 7161. If a sample in a film form is available, the Young's modulus can be measured as per JIS K 7127 using a tensile tester (trade name: AG-X by Shimadzu Corporation).

If a sample in a film form is not available, it is possible to find the Young's modulus of the sample by measuring the international rubber hardness degree (IRHD) of the sample as per JIS K 6253 and converting the measured hardness using a graph adapted to convert an international rubber hardness degree into a Young's modulus. Alternatively, the Young's modulus can be measured using a microhardness tester such as a surface film physical property tester (Fischer Scope HM-500 by Fischer Instruments K.K.). Still alternatively, if the sample is small, the Young's modulus can be measured using an AFM (refer to P.81-P.111 in Polymer Nanomaterials from Kyoritsu Shuppan Co., Ltd).

If the Young's modulus is likely to be less than 1 MPa as when the sample is in a gel form, it is possible to find the Young's modulus by measuring the penetration of the sample and finding the Young's modulus based on the measured penetration using the correlation between the penetration and Young's modulus as per JIS K 2220. It should be noted that the term “Young's modulus” in the present technology includes the virtual Young's modulus of a liquid target and that of an open space, and we assume that the virtual Young's modulus of an open space is 0 MPa.

The entry of moisture into the photoelectric conversion element 101 is likely to take place through the sealing portion 101e. In the present technology, however, the sealing portion 101e of the photoelectric conversion element 101 is covered with the covering section 5, thus suppressing the entry of moisture into the photoelectric conversion element 101 through the sealing portion 101e. From the viewpoint of better suppressing the entry of moisture into the photoelectric conversion element 101, the proportion of the sealing portion 101e to the photoelectric conversion element 101 as a whole should preferably be as small as possible. For example, if the sealing portion 101e is formed on the lateral side of the photoelectric conversion element 101, the thickness of the covering section 5 along the thickness of the photoelectric conversion element 101 should preferably be small, and the thickness of the covering section 5 should preferably be, for example, 1 mm or less. More specifically, the thickness of the same section 5 should preferably be, for example, about 0.4 mm to 0.6 mm. Of course, the thickness of the covering section 5 may be 1 mm or more because the thick covering section 5 is expected to provide improved stress absorption.

### (Anchoring Layer)

The anchoring layer 7 contains a set adhesive as a main ingredient. The adhesive contains one or more adhesives selected, for example, from a group of thermoplastic, thermosetting, room-temperature-setting and energy ray-setting adhesives as main ingredients. The adhesive should preferably contain at least either a room-temperature-setting or energy ray-setting adhesive as a main ingredient from the viewpoint of suppressing the reduction in performance of the photoelectric conversion element 101. The anchoring layer 7 may further contain, as necessary, a hardener, catalyst, accelerant, solvent, diluent, plasticizer, tackifier, filler, age resistor or adhesion promoter. The anchoring layer 7 may still further contain, as necessary, fine particles. Both organic and inorganic fine particles may be, for example, used as fine particles.

As a thermoplastic adhesive, for example, vinyl acetate-based adhesive, polyvinyl alcohol-based adhesive, polyvinyl acetal-based adhesive, vinyl chloride-based adhesive, acrylic adhesive, epoxy-based adhesive, polyethylene-based adhesive and cellulose-based adhesive may be used alone or two or more thereof may be mixed. More specifically, ethylene vinyl acetate (EVA) and polyvinyl butyral (PVB) are preferred. A hot-melt adhesive may also be used as a thermoplastic adhesive.

As a thermosetting adhesive, for example, urea-based adhesive, resorcinol-based adhesive, melamine-based adhesive, phenol-based adhesive, epoxy-based adhesive, polyurethane-based adhesive, polyester-based adhesive, polyimide-based adhesive and polyaromatic-based adhesive may be used alone or two or more thereof may be mixed.

As a room-temperature-setting adhesive, for example, anaerobic adhesive, two-liquid mixture epoxy-based adhesive, polyester-based adhesive, acrylic adhesive, modified acrylic adhesive, urethane-based adhesive, and silicone-based adhesive may be used alone or two or more thereof may be mixed. Alternatively, for example, liquid glass may be used which contains silica solution as a main ingredient and sets and changes into a solid, i.e., amorphous glass, when left exposed to air at room temperature.

Energy ray-setting adhesive is a resin composition which sets when irradiated with an energy ray. Here, the term “energy ray” refers to that which can trigger the polymerization reaction involving radicals, cations and anions such as electron ray, ultraviolet ray, infrared ray, laser beam, visible light, nonionizing radiation (e.g., X—, α, β and γ rays), microwave and high frequency. Further, energy ray-setting resin composition may be an organic/inorganic hybrid material. Still further, two or more different energy ray-setting resin compositions may be mixed for use. An ultraviolet-setting adhesive which sets with ultraviolet ray is preferred for use as an energy ray-setting adhesive.

### (Hollow Layer)

The hollow layer 10 is provided as necessary and should preferably be in a dry air, inert gas or vacuum atmosphere because this can suppress the characteristic degradation of the photoelectric conversion element 101. Among inert gases are Ar (argon) and Kr (krypton) gases.

### (Positional Relationship Between Photoelectric Conversion Element and Covering Section)

FIG. 2B is a cross-sectional view illustrating an example of positional relationship between the sealing portion of the photoelectric conversion element and the surface of the covering section. The photoelectric conversion element 101 has the sealing portion 101e on the lateral side a3 of the peripheral portion of the photoelectric conversion element 101. More specifically, a gap portion 101b is formed by the transparent base material 23 and opposed base material 25 between the peripheral portions thereof. The gap portion 101b is filled with the sealant 27, thus forming the sealing portion 101e of the photoelectric conversion element 101. In the first embodiment, for example, the anchoring layer 7 lies between the rear side a2 of the photoelectric conversion element 101 and the second inner side S2 of the housing body 3 as illustrated in FIG. 2B, thus anchoring the photoelectric conversion element 101 to the second inner side S2 of the housing body 3 with the anchoring layer 7.

Further, in the first embodiment, the sealing portion 101e provided on the peripheral portion of the lateral side a3 of the photoelectric conversion element 101 is covered with the covering section 5 as illustrated in FIG. 2B. The covering section 5 should preferably cover at least part of the sealing portion 101e, and more preferably all of the sealing portion 101e. For example, if the covering section 5 is formed to extend from the second base material 15 to the transparent base material 23, the same section 5 need only be at least taller than the sealing portion 101e in order for the same section 5 to fully cover the sealing portion 101e. The covering section 5 may lie over the lateral side of the transparent base material 23. The incident side a1 of the photoelectric conversion element 101 may be covered with the covering section 5. Alternatively, the incident side a1 thereof may be left open to the hollow layer 10 without being covered with the covering section 5.

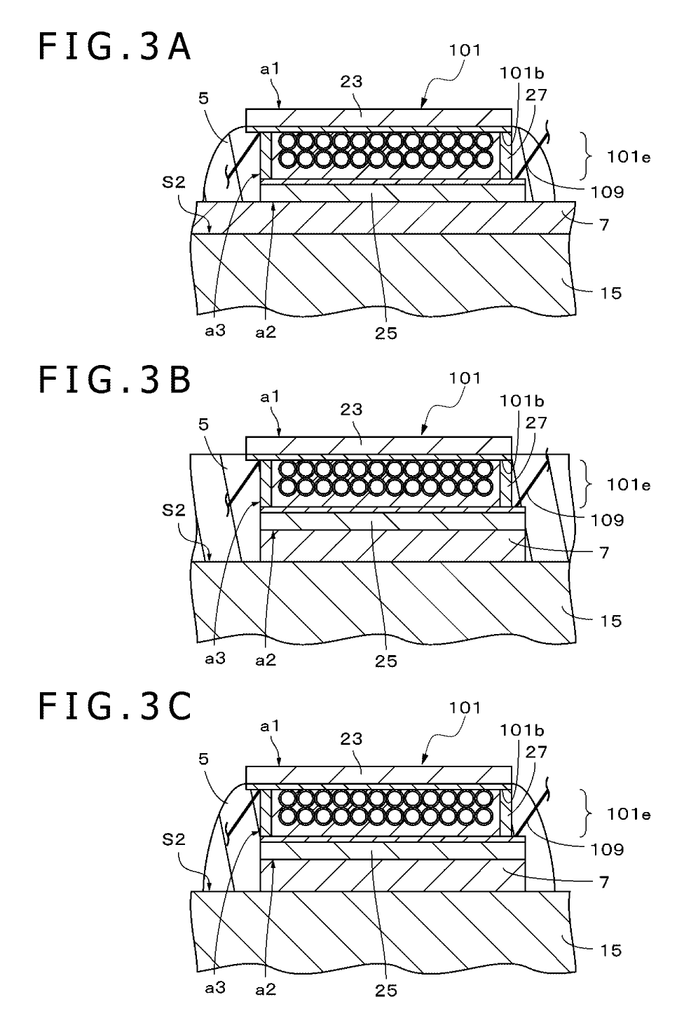

FIGS. 3A to 3C are cross-sectional views illustrating configuration examples of positional relationship between the sealing portion of the photoelectric conversion element and the surface of the covering section. FIG. 3A illustrates a configuration example in which the covering section 5 is formed in part of the surface of the anchoring layer 7 excluding the area where the photoelectric conversion element 101 is anchored. The covering section 5 need only cover the sealing portion 101e provided on the peripheral portion of the lateral side a3 of the photoelectric conversion element 101. There is no need to form the same section 5 over the entire surface of the anchoring layer 7 excluding the area where the photoelectric conversion element 101 is anchored as illustrated in FIG. 3A.

FIG. 3B illustrates a configuration example in which the anchoring layer 7 lies only in the area of the second inner side S2 of the housing body 3 where the rear side a2 of the photoelectric conversion element 101 and the second inner side S2 of the housing body 3 are opposed to each other. At this time, the covering section 5 is formed to have a height extending from the second inner side S2 of the housing body 3 to the transparent base material 23 of the photoelectric conversion element 101.

FIG. 3C illustrates a configuration example in which the anchoring layer 7 lies only in the area of the second inner side S2 of the housing body 3 where the rear side a2 of the photoelectric conversion element 101 and the second inner side S2 of the housing body 3 are opposed to each other as does FIG. 3B. At this time, it is unnecessary to form the covering section 5 over the entire surface of the second inner side S2 of the housing body 3 excluding the area where the anchoring layer 7 is formed as in the configuration example shown in FIG. 3A.

### [Manufacturing Method of Photoelectric Conversion Element Module]

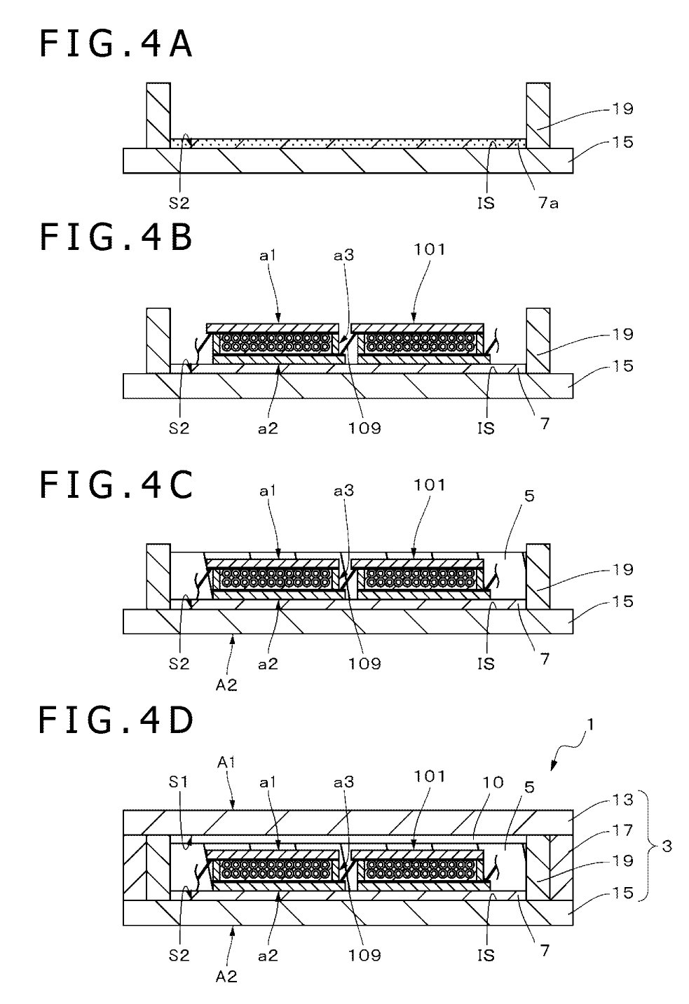

FIGS. 4A to 4D are process diagrams illustrating examples of manufacturing steps of the photoelectric conversion element module according to the first embodiment of the present technology.

First, as illustrated in FIG. 4A, the shielding material 19 is formed on the peripheral portion of the second inner side S2. Then, an adhesive layer 7a in a liquid or molten form adapted to form the anchoring layer 7 is formed in a space surrounded by the shielding material 19. This adhesive layer 7a contains the above adhesive as a main ingredient.

Next, as illustrated in FIG. 4B, the rear side a2 of the photoelectric conversion element 101 is affixed to the adhesive layer 7a. Next, for example, the adhesive layer 7a in a liquid or molten form is set by cooling, by heating, at room temperature or by energy ray, thus forming the anchoring layer 7 on the second inner side S2. This allows for the photoelectric conversion element 101 to be anchored to the second inner side S2.

If a thermoplastic or thermosetting adhesive is used as an adhesive, it is preferred to minimize the impact of pressure and heat applied to the photoelectric conversion element 101. More specifically, if a thermoplastic adhesive is used as an adhesive, for example, it is preferred that the photoelectric conversion element 101 should be placed on the thermoplastic adhesive for bonding after softening and liquefaction of the thermoplastic adhesive. The reason for this is that continuous heating stress can be reduced. From the viewpoint of reducing the impact of heating on the photoelectric conversion element 101, it is preferred to cool the incident side a1, i.e., the side opposite to the bonded side (rear side a2), of the photoelectric conversion element 101. Further, a small pressure may be applied to the incident side a1, i.e., the side opposite to the bonded side (rear side a2), of the photoelectric conversion element 101 as necessary. This allows for firmer bonding of the photoelectric conversion element 101.

If a room-temperature-setting adhesive is used, it is possible to keep thermal stress on the photoelectric conversion element 101 to an insignificant level by using an adhesive whose temperature rise during setting is a maximum of 80° C. If an ultraviolet-setting adhesive is used, it is possible to bond the photoelectric conversion element 101 without causing performance degradation of the photoelectric conversion element 101 by bonding the rear side a2, i.e., the side not contributing to power generation, of the photoelectric conversion element 101 by ultraviolet radiation.

Next, as illustrated in FIG. 4C, the composition in a liquid or molten form adapted to form the covering section is arranged in a space surrounded by the shielding material 19. At this time, the sealing portion 101e provided on the lateral side a3 of the photoelectric conversion element 101 is covered with the composition adapted to form the covering section. This composition contains the above resin material, synthetic or natural rubber as a main ingredient. The composition adapted to form the covering section may be subjected to degassing treatment such as vacuum degassing followed by drying or setting as necessary, thus forming the covering section 5.

Next, as illustrated in FIG. 4D, the second base material 15, to which the photoelectric conversion element 101 is anchored, and the first base material 13, are arranged to be opposed to each other in such a manner that the first and second inner sides S1 and S2 are opposed to each other. At the same time, the first and second base materials 13 and 15 are affixed together via the sealant 17 provided on the peripheral portions thereof. An inert gas such as Ar or Kr gas is filled, as necessary, into a space formed by the covering section 5, shielding material 19 and first inner side S1. The above steps provide the photoelectric conversion element module 1 according to the first embodiment of the present technology.

### First Modification Example

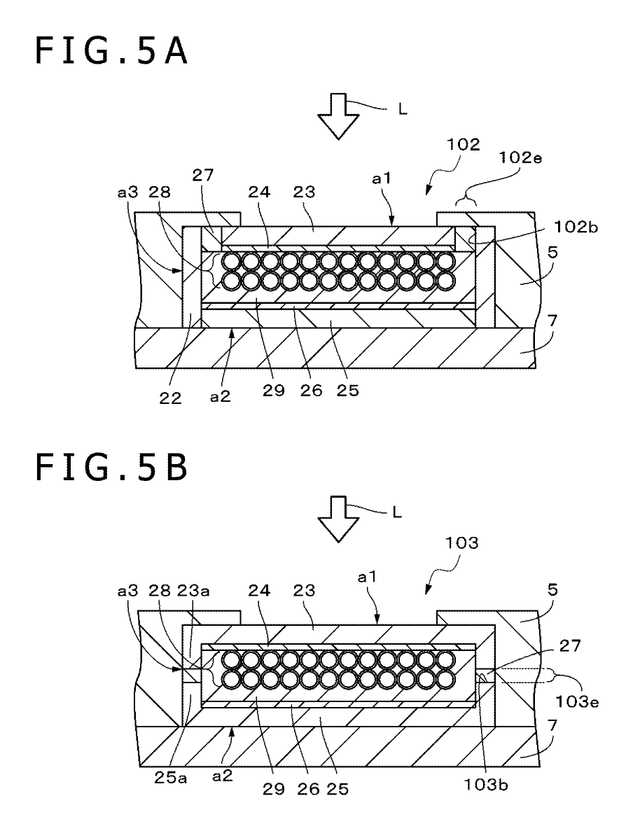

FIG. 5A is a cross-sectional view illustrating a first modification example of the photoelectric conversion element module according to the first embodiment of the present technology. More specifically, a side wall portion 22 projecting toward the transparent base material 23 is provided on the peripheral portion of the opposed base material 25 of a photoelectric conversion element 102. Further, the opposed base material 25 is arranged on the inside of the tip portion of the side wall portion 22, and a gap portion 102b is formed between the tip portion of the side wall portion 22 and the edge portion of the transparent base material 23. The gap portion 102b is filled with the sealant 27, thus forming a sealing portion 102e. The same materials as those for the opposed base material 25 can be used as the side wall portion 22. The side wall portion 22 and the opposed base material 25 are molded separately or integrally. From the viewpoint of productivity, the side wall portion 22 and opposed base material 25 should preferably be molded integrally.

The photoelectric conversion element 102 has the sealing portion 102e on the incident side a1 of the peripheral portion of the photoelectric conversion element 102. The photoelectric conversion element 102 is buried in the covering section 5 from the rear side a2 thereof to the peripheral portion of the incident side a1 thereof, and the sealing portion 102e provided on the peripheral portion of the incident side a1 is covered with the covering section 5. In contrast, the portions other than the peripheral portion of the incident side a1 of the photoelectric conversion element 102, i.e., the portion contributing to photoelectric conversion, are exposed to the hollow layer 10 without being covered with the covering section 5.

### Second Modification Example

FIG. 5B is a cross-sectional view illustrating a second modification example of the photoelectric conversion element module according to the first embodiment of the present technology. A photoelectric conversion element 103 has a sealing portion 103e on the lateral side a3 of the peripheral portion of the photoelectric conversion element 103. More specifically, a side wall portion 23a projecting toward the opposed base material 25 is provided on the peripheral portion of the transparent base material 23. A side wall portion 25a projecting toward the transparent base material 23 is provided on the peripheral portion of the opposed base material 25. Further, a gap portion 103b is formed between the tip portions of the side wall portions 23a and 25a. The gap portion 103b is filled with the sealant 27, thus forming the sealing portion 103e.

The photoelectric conversion element 103 is buried in the covering section 5 from the rear side a2 thereof to the sealing portion 103e of the lateral side a3 thereof, and the sealing portion 103e provided on the lateral side a3 is covered with the covering section 5. In contrast, the incident side a1 of the photoelectric conversion element 103 is exposed to the hollow layer 10 without being covered with the covering section 5.

### Third Modification Example

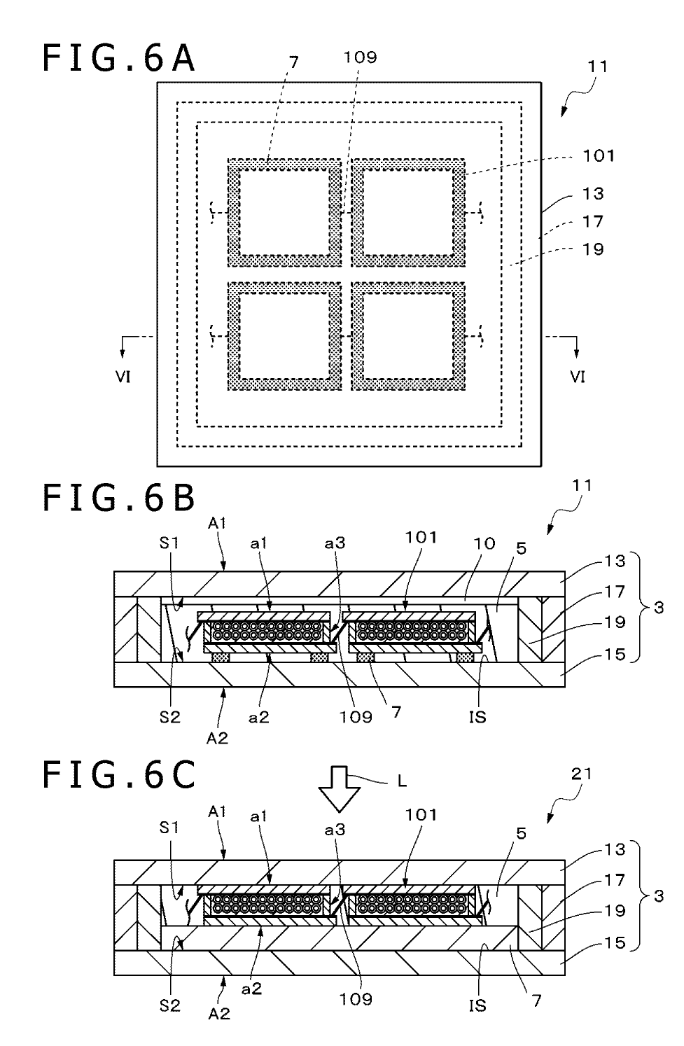

FIG. 6A is a cross-sectional view illustrating a third modification example of the photoelectric conversion element module according to the first embodiment of the present technology. FIG. 6B is a cross-sectional view along line VI-VI in FIG. 6A. As illustrated in FIGS. 6A and 6B, the anchoring layer 7 may be in the form of a rib. FIGS. 6A and 6B illustrate an example in which the single anchoring layer is provided continuously on the entire peripheral portion of the rear side a2 of the photoelectric conversion element 101. However, the configuration of the anchoring layer 7 is not limited to this example. Instead, the plurality of anchoring layers 7 in the form of columns may be provided, for example, intermittently on the peripheral portion of the rear side a2 of the photoelectric conversion element 101. It should be noted that the anchoring layers 7 of a photoelectric conversion element module 11 are shaded in FIGS. 6A and 6B.

At this time, it is preferred to use an elastic resin as the anchoring layer 7. If the anchoring layer 7 can produce a compression stress, the rear side a2 of the photoelectric conversion element 101 can be supported by the compression stress produced by the anchoring layer 7 even in the event of a change in the operating environment temperature, thus providing improved reliability of the photoelectric conversion element module.

### Fourth Modification Example

FIG. 6C is a cross-sectional view illustrating a fourth modification example of the photoelectric conversion element module according to the first embodiment of the present technology. In a photoelectric conversion element module 21 according to the fourth modification example, the incident side a1 of the photoelectric conversion element 101 is in close contact with the first inner side S1 of the housing body 3. At this time, it is preferred that the transparent base material 23 of the photoelectric conversion element 101 and the first base material 13 of the housing body 3 should have the same or roughly the same refractive index. The reason for this is that the reflection of the incident light L can be suppressed at the interface between the incident side a1 of the photoelectric conversion element 101 and the first inner side S1 of the housing body 3.

In the fourth modification example, the incident side a1 of the photoelectric conversion element 101 is in close contact with the first inner side S1 of the housing body 3. This contributes to a reduced number of interfaces of the incident side a1 of the photoelectric conversion element 101, thus providing better utilization efficiency of the incident light L than when the covering section 5 or hollow layer 10 lies between the incident side a1 of the photoelectric conversion element 101 and the first inner side S1 of the housing body 3.

### (Effect)

If a photoelectric conversion element having a sealing structure is anchored inside the housing body as in a dye sensitized solar cell, external force exerted on the housing body propagates to the photoelectric conversion element via anchoring members such as adhesive, resulting in damage to the photoelectric conversion element. Further, a force is exerted on the photoelectric conversion element due to swelling of a resin material caused by moisture absorption or due to the difference in thermal expansion coefficient caused by junction of dissimilar materials, resulting in damage to the sealing structure of the photoelectric conversion element.

In the present technology, when the one or more photoelectric conversion elements 101, each having a sealing structure, are fitted into the housing space IS of the housing body 3, only one of the transparent base material 23 and opposed base material 25 of each of the photoelectric conversion elements 101 is anchored to the inner side of the housing body 3. Therefore, the external force exerted on the photoelectric conversion element module 1 does not directly propagate to both of the transparent base material 23 and opposed base material 25 through the medium of the anchoring member which is not the case if both of the transparent base material 23 and opposed base material 25 of each of the photoelectric conversion elements 101 are anchored to the inner side of the housing body 3 using the anchoring member.

Therefore, the present technology prevents damage to the sealing structure of each of the photoelectric conversion elements 101 caused by the propagation of the external force exerted on the photoelectric conversion element module 1 to both of the transparent base material 23 and opposed base material 25. That is, it is possible to suppress the cleavage of the sealing structure of the photoelectric conversion element 101 even if an external force is exerted on the photoelectric conversion element module 1. Therefore, the present technology prevents damage to the sealing structure of the photoelectric conversion element 101 even if an external force is exerted on the photoelectric conversion element module 1, for example, during the manufacture of the same module 1. This provides the photoelectric conversion element module 1 using the plurality of photoelectric conversion elements 101, each having a sealing structure.

Further, in the present technology, the covering section 5 covers the sealing portion 101e of the photoelectric conversion element 101, thus reinforcing the sealing portion 101e. Further, it is possible to suppress the entry of moisture into the photoelectric conversion element 101 from the sealing portion 101e. This contributes to improved weather resistance of the photoelectric conversion element module 1, thus making it possible to implement the photoelectric conversion element module 1 that can meet the requirements for reliable weather resistance for outdoor use such as architectural structures and ordinary homes.

Further, in the present technology, the Young's modulus of the covering section 5 is 0 MPa or more and 20 MPa or less. Therefore, even if a stress is generated due to swelling of a resin material caused by moisture absorption or due to the difference in thermal expansion coefficient caused by junction of dissimilar materials, the covering section 5 serves as a cushioning material, thus suppressing the cleavage of the sealing structure of the photoelectric conversion element 101.

As described above, in the present technology, if the photoelectric conversion element 101 is anchored or sealed in the housing space IS of the housing body 3, there is a significant difference in restriction structure between the incident side a1 of the photoelectric conversion element 101 and the rear side a2 opposite to the incident side a1. In other words, in the present technology, the function adapted to anchor the photoelectric conversion element 101 to the housing space IS and that adapted to reinforce the sealing portion 101e of the photoelectric conversion element 101 are separately assumed by the anchoring layer 7 and covering section 5. The incident side a1 of the photoelectric conversion element 101 and the rear side a2 opposite to the incident side a1 are not firmly anchored to the inner side of the housing body 3 by the same anchoring member, thus suppressing the cleavage of the sealing structure of the photoelectric conversion element 101.

It should be noted that, as described above, the hollow layer 10 may be provided between the incident side a1 of the photoelectric conversion element 101 and the first inner side S1 of the housing body 3, thus providing secondary functions such as thermal insulation and soundproofing to the photoelectric conversion element module. If the second and first base materials 15 and 13 of the housing body 3 are made of glass plates, the photoelectric conversion element module can be used as eco-friendly glass such as multi-layer glass.

Further, if at least either a room-temperature-setting or energy ray-setting adhesives is used as an adhesive adapted to form the anchoring layer 7, it is possible to manufacture the photoelectric conversion element module without causing thermal stress to the photoelectric conversion elements 101 in the setting process of the adhesive. More specifically, it is possible to manufacture the photoelectric conversion element module without applying a temperature in excess of their heat-resistant temperatures to the sensitizing dye 28b, electrolyte layer 29, sealant 27 and other members made of organic substances constituting the photoelectric conversion elements 101. This prevents performance degradation and damage to the members caused by heat.

### 2. Second Embodiment

### Configuration of the Photoelectric Conversion Element Module

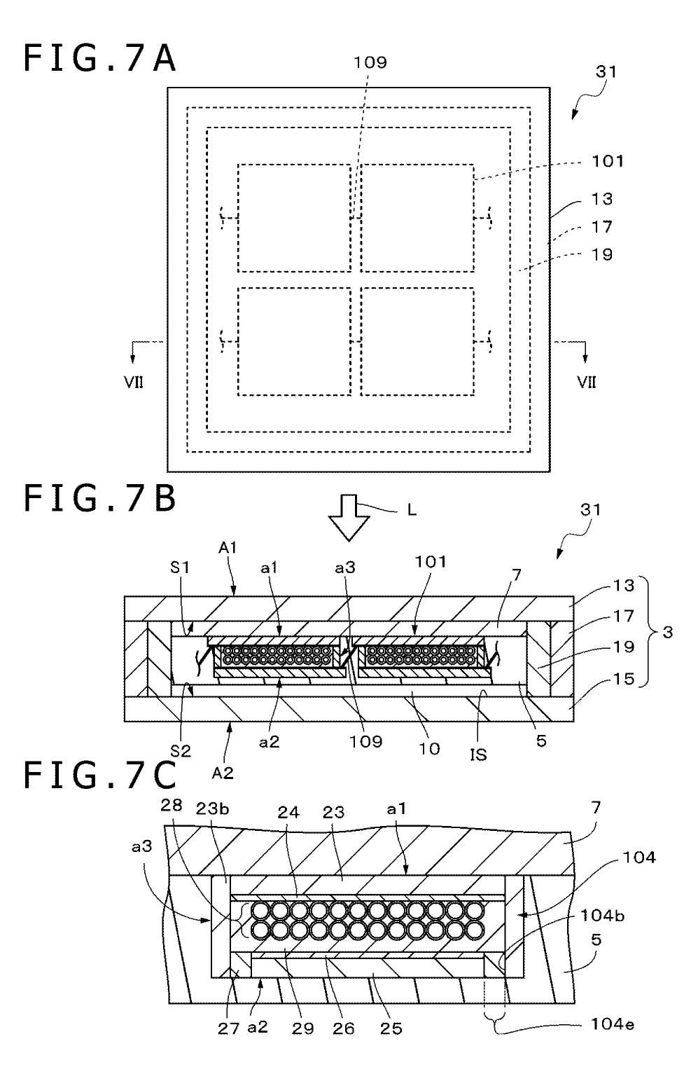

FIG. 7A is a plan view illustrating a configuration example of a photoelectric conversion element module according to a second embodiment of the present technology. FIG. 7B is a cross-sectional view along line VII-VII in FIG. 7A. The second embodiment is common to the first embodiment in that the sealing portion of each of the photoelectric conversion elements 101 is covered with the covering section 5, and that the Young's modulus of the covering section is 0 MPa or more and 20 MPa or less. The second embodiment differs from the first embodiment in that the anchoring layer 7 lies between the incident side a1 of each of the one or more photoelectric conversion elements 101 and the first inner side S1 of the housing body 3, and that each of the photoelectric conversion elements 101 is anchored to the inner side S1 of the housing body 3 with the anchoring layer 7. At this time, the anchoring layer 7 should preferably be transparent.

As described above, in the present technology, if each of the photoelectric conversion elements 101 is anchored inside the housing body 3 with the anchoring layer 7, the anchoring layer 7 may be formed either between the incident side a1 and first inner side S1 or between the rear side a2 and second inner side S2. In the present technology, only one of the incident side a1 and rear side a2 of each of the photoelectric conversion elements 101 is anchored with the anchoring layer 7. That is, in the present technology, both of the incident side a1 and rear side a2 of each of the photoelectric conversion elements 101 are not anchored with the single anchoring layer 7.

### First Modification Example

FIG. 7C is a cross-sectional view illustrating a first modification example of the photoelectric conversion element module according to the second embodiment of the present technology. A photoelectric conversion element 104 has a sealing portion 104e on the rear side a2 of the peripheral portion of the same element 104. More specifically, a side wall portion 23b projecting toward the opposed base material 25 is provided on the peripheral portion of the transparent base material 23. Further, the opposed base material 25 is arranged on the inside of the tip portion of the side wall portion 23b, and a gap portion 104b is formed between the tip portion of the side wall portion 23b and the edge portion of the opposed base material 25. The gap portion 104b is filled with the sealant 27, thus forming the sealing portion 104e. The same materials as those for the transparent base material 23 can be used as the side wall portion 23b. The side wall portion 23b and transparent base material 23 are molded separately from or integrally with each other. From the viewpoint of productivity, they should preferably be molded integrally.

The rear side a2 of the photoelectric conversion element 104 is buried in the covering section 5. As a result, the sealing portion 104e provided on the peripheral portion of the rear side a2 is covered with the covering section 5. In the configuration example shown in FIG. 7C, the covering section 5 does not lie between the incident side a1 of the photoelectric conversion element 101 and the first inner side S1 of the housing body 3. Therefore, an opaque material can be used as the covering section 5. This provides a wider selection of materials adapted to form the covering section 5.

### Second Modification Example

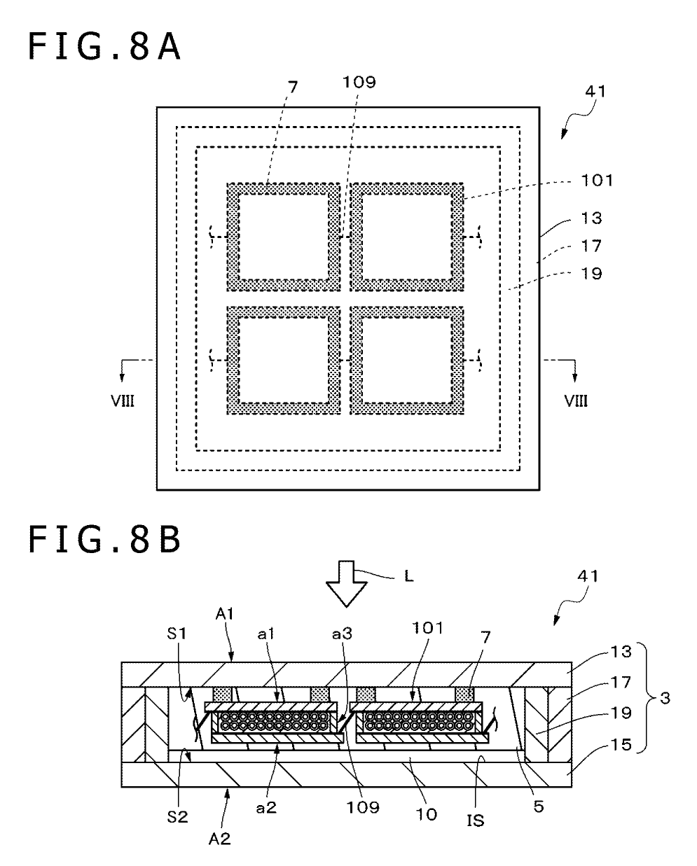

FIG. 8A is a plan view illustrating a second modification example of the photoelectric conversion element module according to the second embodiment of the present technology. FIG. 8B is a cross-sectional view along line VIII-VIII in FIG. 8A. As illustrated in FIGS. 8A and 8B, the anchoring layer 7 may be in the form of a rib. FIGS. 8A and 8B illustrate an example in which the single anchoring layer is provided continuously on the entire peripheral portion of the incident side a1 of the photoelectric conversion element 101. However, the configuration of the anchoring layer 7 is not limited to this example. Instead, the plurality of anchoring layers 7 in the form of columns may be provided, for example, intermittently on the peripheral portion of the incident side a1 of the photoelectric conversion element 101. It should be noted that the anchoring layers 7 of a photoelectric conversion element module 41 are shaded in FIGS. 8A and 8B.

In the photoelectric conversion element module 41, the incident side a1 of the photoelectric conversion element 101 and the first inner side S1 of the housing body 3 are affixed together, for example, with an energy ray-setting adhesive. An ultraviolet-setting adhesive is preferred for use as an energy ray-setting adhesive.

It should be noted that the anchoring layer 7 in the form of a rib or the same layers 7 in the form of columns, for example, to suppress the reduction in amount of light reaching the area contributing to power generation should preferably be provided on the peripheral portion of the incident side a1 of the photoelectric conversion element 101. At this time, it is possible to radiate energy rays such as ultraviolet rays onto the peripheral portion of the incident side a1 of the photoelectric conversion element 101 and set the energy ray-setting adhesive by arranging a light-shielding mask above the incident side A1 of the photoelectric conversion element module 41. Energy rays such as ultraviolet rays may be radiated in a linear manner rather than radiating such rays using a light-shielding mask.

If the anchoring layer 7 in the form of a rib or the same layers 7 in the form of columns are provided on the peripheral portion of the photoelectric conversion element 101, an opaque material can be used as the anchoring layers 7. This provides a wider selection of adhesives adapted to form the anchoring layers 7. Alternatively, a two-liquid-setting adhesive may be used rather than an energy ray-setting adhesive. Still alternatively, a double-sided tape having an agglutinant layer that contains, for example, an acrylic resin as a main ingredient may be used. This makes it possible to anchor the housing body 3 to the photoelectric conversion element 101 in a simpler and more convenient manner.

FIG. 8B illustrates an example in which the covering section 5 lies between the incident side a1 of the photoelectric conversion element 101 and the first inner side S1 of the housing body 3. However, the hollow layer 10 may be provided between the incident side a1 of the photoelectric conversion element 101 and the first inner side S1 of the housing body 3 because this ensures exposure of the area of the incident side a1 of the photoelectric conversion element 101 contributing to power generation.

In the second embodiment, the sealing portion of each of the photoelectric conversion elements 101 is covered with the covering section 5, and the Young's modulus of the covering section is 0 MPa or more and 20 MPa or less. As a result, the second embodiment suppresses the cleavage of the sealing structure of each of the photoelectric conversion elements 101 as does the first embodiment.

### 3. Third Embodiment

### Configuration of the Photoelectric Conversion Element Module

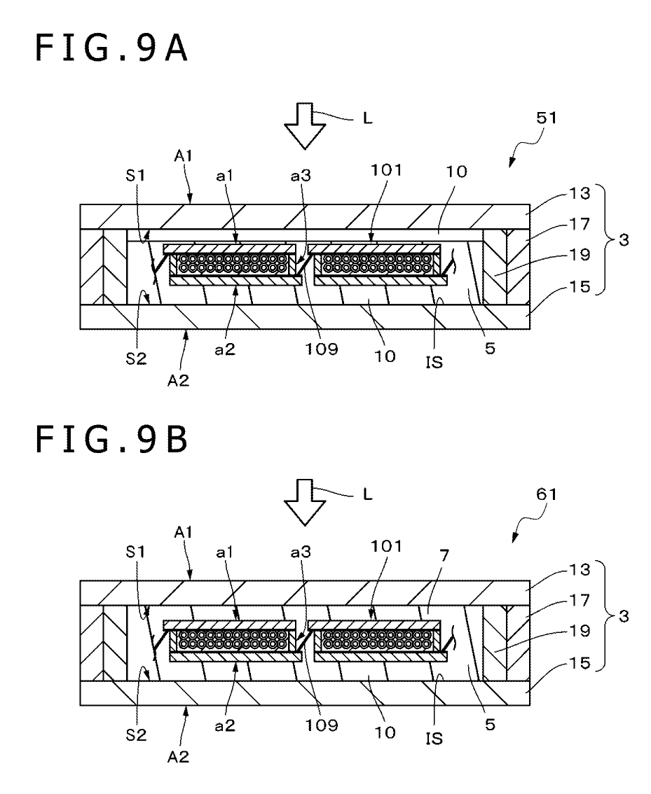

FIG. 9A is a cross-sectional view illustrating a configuration example of a photoelectric conversion element module according to a third embodiment of the present technology. The third embodiment is common to the first embodiment in that the sealing portion of each of the photoelectric conversion elements 101 is covered with the covering section 5, and that the Young's modulus of the covering section 5 is 0 MPa or more and 20 MPa or less. The third embodiment differs from the first embodiment in that the covering section 5 serves also as the anchoring layer 7 in the first embodiment, and that the one or more photoelectric conversion elements 101 are supported by the covering section 5 inside the housing body 3.

A photoelectric conversion element module 51 shown in FIG. 9A does not include any anchoring layer inside the housing space IS. Instead, the one or more photoelectric conversion elements 101 are supported by the covering section 5 inside the housing body 3. If the covering section 5 is not in a liquid form, the photoelectric conversion elements 101 are buried in the covering section 5 as shown in FIG. 9A, thus supporting the same elements 101 inside the housing body 3. At this time, the covering section 5 is soft, thus allowing for the same section 5 to relax the force exerted on the photoelectric conversion element module. This suppresses damage to the sealing structures of the photoelectric conversion elements 101.

### First Modification Example

FIG. 9B is a cross-sectional view illustrating a first modification example of the photoelectric conversion element module according to the third embodiment of the present technology. As illustrated in FIG. 9B, the housing space IS may be filled with the covering section 5. At this time, the photoelectric conversion elements 101 are buried in the covering section 5. If a photoelectric conversion element module 61 of the first modification example is left standing horizontally, for example, the covering section 5 in a liquid form can be used.

In the third embodiment, the sealing portion of each of the photoelectric conversion elements 101 is covered with the covering section 5, and that the Young's modulus of the covering section 5 is 0 MPa or more and 20 MPa or less. As a result, the third embodiment suppresses the cleavage of the sealing structure of each of the photoelectric conversion elements 101 as does the first embodiment.

### 4. Fourth Embodiment

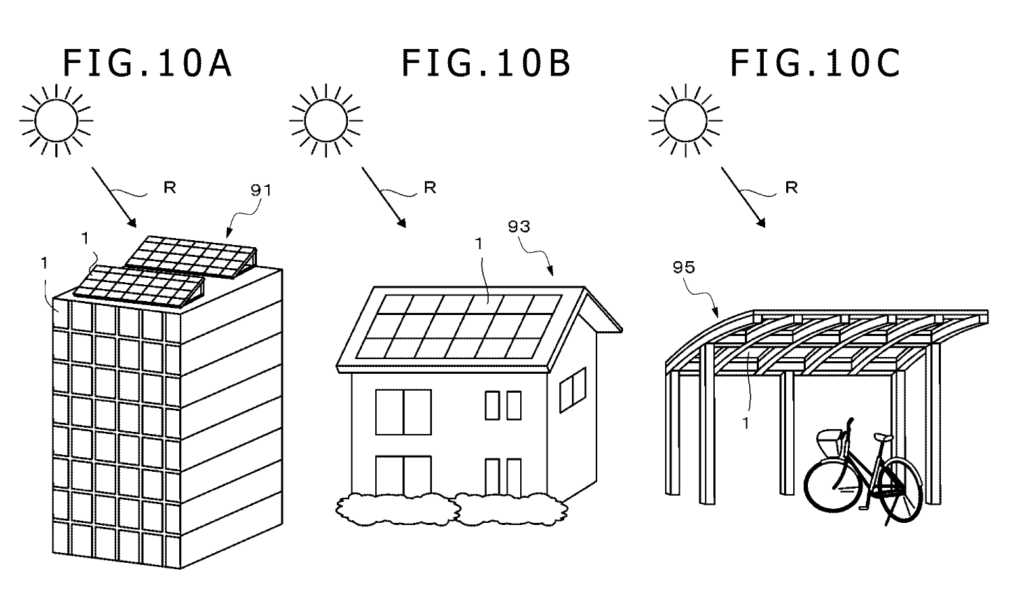

FIGS. 10A to 10C are diagrams illustrating examples of architectural structures according to the present technology. Among architectural structures are buildings, condominiums and other large-size architectural structures. Architectural structures are not limited to the above, and any architectural structure is basically acceptable so long as it has outer wall surfaces. Among specific examples of architectural structures are detached houses, apartment houses, station buildings, school buildings, government office buildings, sports stadiums, ballparks, hospitals, churches, factories, warehouses, huts, garages, bridges and stores.

FIG. 10A is a diagram illustrating an example of a building with the photoelectric conversion element modules 1 installed thereon. As illustrated in FIG. 10A, the photoelectric conversion element modules 1 according to the first embodiment are, for example, installed horizontally or in a tilted position facing southeast to southwest (if the building 91 is erected in the northern hemisphere) on the roof of a building 91. The reason for this is that it is possible to receive sunlight R more effectively by installing the photoelectric conversion element modules 1 in such an orientation.

As illustrated in FIG. 10A, the photoelectric conversion element modules 1 may be installed on light collection sections such as windows. If the photoelectric conversion element modules 1 are installed on windows and other light collection sections, it is preferred that the photoelectric conversion elements and/or photoelectric conversion element modules should be arranged between two transparent base materials. Among transparent base materials that can be used are glass plates. At this time, it is preferred that one of the two base materials should be anchored as necessary to prevent the photoelectric conversion elements from moving inside the photoelectric conversion element modules 1.

The photoelectric conversion element modules 1 are, for example, electrically connected to the power system of the building. Power obtained by the photoelectric conversion element modules 1 is supplied, for example, for use inside the building for lighting and air conditioning purposes or is externally fed for sale. Power may be stored in an accumulator as necessary. If the architectural structure is a bridge or other structure, it is preferred to include an output socket adapted to externally feed power obtained by the photoelectric conversion element modules 1. The reason for this is that power, obtained by the photoelectric conversion element modules 1, can be used to charge mobile devices and as an emergency power source in the event of a disaster.

FIG. 10B is a diagram illustrating an example of a house with the photoelectric conversion element modules 1 installed thereon. As illustrated in FIG. 10B, the photoelectric conversion element modules 1 according to the first embodiment are, for example, installed horizontally or in a tilted position on the roof of a house 93.

FIG. 10C is a diagram illustrating an example of a rain shelter installed in a bicycle parking area and having the photoelectric conversion element modules 1. As illustrated in FIG. 10C, a rain shelter 95 installed in the bicycle parking area has, for example, the photoelectric conversion element modules 1 disposed thereon. The rain shelter 95 may have the functions of a charging stand for electric vehicles and other purposes.

Among other architectural structures are soundproof walls along roads and railway tracks and arcade roofs. It is particularly preferred that an architectural structure should be built to have at least one light collection section. The present technology is applicable to a sunshade structure called an artificial shade.

The preferred embodiments of the present technology have been specifically described above. However, the present technology is not limited to the above embodiments and may be modified in various ways based on the technical concept of the present technology.

For example, a plurality of fine particles (beads) having optical diffusion property may be disposed between the incident side a1 of the photoelectric conversion element 101 and the first inner side S1 of the housing body 3 as a supporting member. This allows for the fine particles to diffuse the incident light L such as sunlight diagonally falling on the incident side of the photoelectric conversion element module, thus directing the light L toward the photoelectric conversion elements and providing improved light utilization efficiency.

Further, the holding body may have one or more functions selected, for example, from a group of selective wavelength absorption, selective wavelength reflection, anti-staining, anti-reflection, diffusion and hard-coating functions. More specifically, among configurations adapted to impart the above functions to the surface of the housing body are one in which a functional layer is formed on the surface of the housing body and another in which a functional structure (fine structure) is formed on the surface of the housing body. Among configurations adapted to impart the above functions to the inside of the housing body is that in which at least either a functional material or functional structure (fine structure) is included inside the housing body.

For example, a functional layer may be provided on the surface of at least one of the first and second inner sides S1 and S2 of the housing body 3 and the incident and rear sides A1 and A2. One or more layers selected, for example, from a group of a selective wavelength absorption, selective wavelength reflection, anti-staining, anti-reflection, diffusion and hard-coating layers can be used as a functional layers. Ultraviolet absorption layer (UV cutting layer) and heat ray absorption layer (solar shielding function layer) are preferred as selective wavelength absorption layers. Ultraviolet reflection layer (UV cutting layer) and heat ray reflection layer (solar shielding function layer) are preferred as selective wavelength reflection layers. A layer having one or two or more of water-repellent, oil-repellent and self-cleaning functions is preferred as an anti-staining layer. Among types of layers that can be used as an anti-staining layer are optical catalysis layer and fluorine resin layer. If a heat ray absorption or reflection layer is used as a functional layer, the photoelectric conversion element module can be used as a window material such as eco-friendly glass.

Alternatively, a functional structure may be provided on the surface of the housing body. Among functional structures are a fine structure adapted to diffuse the incident light L (diffusion element) and a fine structure adapted to provide reduced reflectance of the incident light L and/or improved transmittance thereof (subwavelength structure).

Still alternatively, a functional material or structure may be provided inside the housing body. For example, fine particles may be added to the inside of the housing body as a functional material.

A functional material or functional structure may be provided, for example, at least inside either the first or second base material. Among materials that can be used as a functional material are optical diffusion fine particles adapted to diffuse light, fluorine resin material adapted to impart anti-staining property to the surface of the housing body, and optical catalyst. Among structures that can be used as a functional structure is a void (cavity portion) adapted to diffuse light.

Further, although examples have been described in the above embodiments in which a dye sensitized photoelectric conversion element is used as a photoelectric conversion element, the photoelectric conversion element is not limited to these examples. Instead, an amorphous photoelectric conversion element, compound semiconductor photoelectric conversion element or thin film polycrystalline photoelectric conversion element may be, for example, used.

Still further, although examples have been described in the above embodiments in which the gap portion provided between the peripheral portions of the transparent base material and opposed base material is sealed with the sealant, the gap portion may be filled with the covering section and sealed with the covering section rather than being sealed with the sealant.

Still further, one or a plurality of base materials may be provided on at least either the incident side A1 or rear side A2 of the housing body in the above embodiments. At this time, the base material and the incident side A1 or rear side A2 of the housing body 3 may be spaced from each other so as to form a hollow layer. The same material as used for the base material according to the first embodiment, for example, may be used as the base material.

It should be noted that, from the viewpoint of ensuring that an external force exerted on the photoelectric conversion element module does not directly propagate to both of the transparent and opposed base materials of the photoelectric conversion element, it is only necessary to anchor only either the transparent or opposed base material of the photoelectric conversion element to the inner side of the housing body.

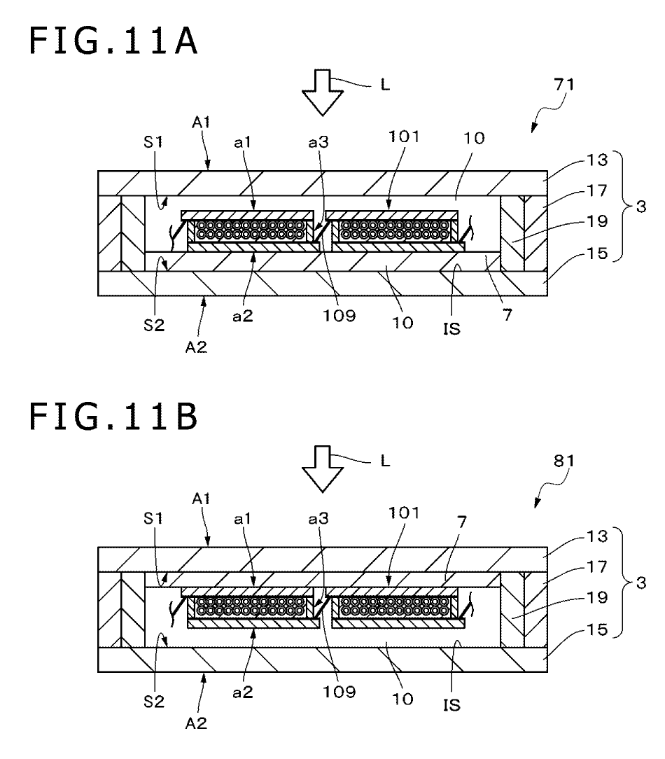

FIG. 11A is a cross-sectional view illustrating a configuration example in which only the opposed base material of the photoelectric conversion element is anchored to the inner side of the housing body with the anchoring layer. FIG. 11B is a cross-sectional view illustrating a configuration example in which only the transparent base material of the photoelectric conversion element is anchored to the inner side of the housing body with the anchoring layer. In a photoelectric conversion element module 71 shown in FIG. 11A, the anchoring layer 7 lies between the rear side a2 of each of the photoelectric conversion elements 101 and the second inner side S2 of the housing body 3, and the plurality of photoelectric conversion elements 101 are anchored to the second inner side S2 of the housing body 3 by the anchoring layer 7. In a photoelectric conversion element module 81 shown in FIG. 11B, the anchoring layer 7 lies between the incident side a1 of each of the photoelectric conversion elements 101 and the first inner side S1 of the housing body 3, and the plurality of photoelectric conversion elements 101 are anchored to the first inner side S1 of the housing body 3 by the anchoring layer 7.

As illustrated in FIGS. 11A and 11B, the sealing portion of each of the photoelectric conversion elements 101 may be left open to ensure that an external force exerted on the photoelectric conversion element module does not directly propagate to both of the transparent and opposed base materials of each of the photoelectric conversion elements.

On the other hand, for example, the configurations, methods, process steps, shapes, materials and values cited above in the embodiments are merely examples, and different configurations, methods, process steps, shapes, materials and values may be used as necessary.

Further, the above configurations, methods, process steps, shapes, materials and values may be combined without departing from the spirit of the present technology.

Still further, the following configurations may also be used in the present technology.

(1) A photoelectric conversion element module including:

a first base material;

a second base material;

a photoelectric conversion element having a light incident side and sealing portion and arranged between the first and second base materials;

an anchoring layer adapted to anchor one of main sides of a light incident side and a side opposite to the light incident side, and one of main sides of the first and second base material opposed to one of the main sides; and

a covering section adapted to cover the sealing portion, in which

the Young's modulus of the covering section is 0 MPa or more and 20 MPa or less.

(2) The photoelectric conversion element module of feature (1), in which

the covering section includes one or more selected from a group of silicone-based resin, modified silicone-based resin, urethane-based resin, polysulfide-based resin, modified polysulfide-based resin, telechelic polyacrylate-based resin, acrylic resin, acrylic urethane-based resin, vinyl acetate-based resin, acrylonitrile, hydrocarbon resin, alkylphenol resin, rosin-based resin, polyvinyl ether, synthetic rubber and natural rubber.

(3) The photoelectric conversion element module of feature (1) or (2) further including:

a hollow layer between the light incident side and one of the first and second base materials.

(4) The photoelectric conversion element module of feature (1) or (2), in which

the light incident side is in close contact with one of the first and second base materials.

(5) The photoelectric conversion element module of feature (1) or (2) further including:

a hollow layer between the main side opposite to the light incident side and one of the first and second base materials.

(6) The photoelectric conversion element module of any one of features (1) to (5), in which

the anchoring layer is formed on at least part of the light incident side or the main side opposite to the light incident side.

(7) The photoelectric conversion element module of feature 6, in which

the anchoring layer is formed in the form of a rib or the anchoring layers are formed in the form of columns.

(8) The photoelectric conversion element module of any one of features (1) to (7), in which

the covering section is formed to have a height extending from the surface of the anchoring layer to the light incident side.

(9) The photoelectric conversion element module of any one of features (1) to (7), in which

the covering section is formed to have a height extending from the main side of the first and second base material opposed to one of the main sides to the light incident side.

(10) The photoelectric conversion element module of any one of features (1) to (9), in which

the photoelectric conversion element includes
a transparent base material,
an opposed base material, and
a power generating element section, and in which

the sealing portion is provided between the peripheral portions of the transparent and opposed base materials.

(11) The photoelectric conversion element module of any one of features (1) to (10), in which

the photoelectric conversion element has a lateral side provided between the peripheral portions of the light incident side and the main side opposite to the light incident side, and in which

the sealing portion is provided on the peripheral portion of the light incident side, that of the main side opposite to the light incident side or the lateral side.

(12) The photoelectric conversion element module of any one of features (1) to (11) further including:

a sealant provided between the peripheral portions of the first and second base materials.

(13) The photoelectric conversion element module of any one of features (1) to (12), in which

the first base material is a first glass plate, and in which

the second base material is a second glass plate.

(14) The photoelectric conversion element module of feature (12) or (13) further including:

a shielding material provided between the peripheral portions of the first and second base materials.

(15) The photoelectric conversion element module of any one of features (1) to (14), in which

the anchoring layer contains one or more adhesives selected from a group of thermoplastic, thermosetting, room-temperature-setting and energy ray-setting adhesives.

(16) The photoelectric conversion element module of feature (15), in which

the energy ray-setting adhesive is an ultraviolet-setting adhesive.

(17) An architectural structure including the photoelectric conversion element module of any one of features (1) to (16).

### Execution Examples

An accelerated deterioration test was performed by preparing samples 1 to 7 of photoelectric conversion element modules to evaluate the presence or absence of damage to the sealing structure of each of the modules. A specific description will be given below of the present technology based on execution examples. However, the present technology is not limited to these execution examples.

### <Sample 1>

First, a photoelectric conversion element was prepared which had an electrolyte layer sealed in a space surrounded by a transparent base material, opposed base material and sealant. A transparent electrode and porous semiconductor layer were formed on the transparent base material. An opposed electrode was formed on the opposed base material. It should be noted that glass plates were used as the transparent and opposed base materials, and that an ultraviolet-setting adhesive was used as a sealant.

Next, a base material made of a glass substrate was prepared in which a shielding material was formed on the peripheral portion of the main sides. Next, ethylene vinyl acetate in a liquid or molten form was poured into a space surrounded by the shielding material, thus forming an adhesive layer containing ethylene vinyl acetate as a main ingredient. Next, a photoelectric conversion element was affixed to the adhesive layer, followed by setting of the same layer, thus forming an anchoring layer made of ethylene vinyl acetate and anchoring the photoelectric conversion element to a main side (second inner side) of the base material.

Next, ethylene vinyl acetate in a liquid or molten form was further poured into the space surrounded by the shielding material until the sealing portion on the lateral side of the photoelectric conversion element was covered. Next, ethylene vinyl acetate in a liquid or molten form was subjected to setting, thus forming a covering section made of ethylene vinyl acetate.

Next, the base material having the photoelectric conversion element anchored thereto and other glass substrate were affixed together via a sealant provided between the peripheral portions thereof. A photoelectric conversion element module of sample 1 was obtained as a result of the above steps.

### <Sample 2>

The photoelectric conversion element module of sample 2 was obtained in the same manner as for sample 1 except that a photoelectric conversion element was anchored to a main side of the base material with a covering section made of ethylene vinyl acetate without forming an anchoring layer. That is, in sample 2, ethylene vinyl acetate in a liquid or molten form was poured into a space surrounded by the shielding material until the sealing portion on the lateral side of the photoelectric conversion element was covered, with a photoelectric conversion element arranged in this space, followed by setting, thus forming a covering section.

### <Sample 3>

The photoelectric conversion element module of sample 3 was obtained in the same manner as for sample 1 except that epoxy resin was used rather than ethylene vinyl acetate to form an anchoring layer and covering section.

### <Sample 4>

The photoelectric conversion element module of sample 4 was obtained in the same manner as for sample 2 except that epoxy resin was used rather than ethylene vinyl acetate to form a covering section.

### <Sample 5>

The photoelectric conversion element module of sample 5 was obtained in the same manner as for sample 2 except that acrylic resin was used rather than ethylene vinyl acetate to form a covering section.

### <Sample 6>

The photoelectric conversion element module of sample 6 was obtained in the same manner as for sample 1 except that acrylic resin was used rather than ethylene vinyl acetate to form an anchoring layer and a silicone gel was used to form a covering portion.

### <Sample 7>

The photoelectric conversion element module of sample 7 was obtained in the same manner as for sample 1 except that a photoelectric conversion element was anchored to a main side of the base material with an anchoring layer made of acrylic resin without forming a covering section. That is, in sample 7, acrylic resin in a liquid or molten form was poured into a space surrounded by the shielding material, thus forming an adhesive layer containing acrylic resin as a main ingredient. Next, a photoelectric conversion element was affixed to the adhesive layer, followed by setting of the adhesive layer, thus forming an anchoring layer made of acrylic resin and anchoring the photoelectric conversion element to a main side (second inner side) of the base material.

Next, the photoelectric conversion element modules of samples 1 and 2 were exposed to a temperature of 140° C. for 30 minutes or so. Further, the photoelectric conversion element modules of samples 3 to 7 were exposed to a temperature of 85° C. and humidity of 85% for 100 hours or so.

Table 1 given below shows the evaluation results of samples 1 to 7 as to the presence or absence of damage to the sealing structure of the photoelectric conversion element. It should be noted that “o” and “x” shown under “Evaluation Result” indicate the following evaluations:

o: No electrolyte leakage was observed in the photoelectric conversion element.
x: An electrolyte leakage was observed in the photoelectric conversion element.

TABLE 1

| | Material | | | | | Evalu- |
|---|---|---|---|---|---|---|
| | Covering | Young's | | Anchoring | Test | ation |
| | Section | Modulus | | Layer | Condition | Result |
| Sample | Ethylene | 30 | [MPa] | Ethylene | High | x |
| 1 | vinyl | | | vinyl | temperature | |
| | acetate | | | acetate | | |
| Sample | Ethylene | 30 | [MPa] | — | High | x |
| 2 | vinyl | | | | temperature | |
| | acetate | | | | | |
| Sample | Epoxy | 3000 | [MPa] | Epoxy | High | x |
| 3 | resin | | | resin | temperature, | |
| | | | | | high humid | |
| Sample | Epoxy | 3000 | [MPa] | — | High | x |
| 4 | resin | | | | temperature, | |
| | | | | | high humid | |
| Sample | Acrylic | 2500 | [MPa] | — | High | x |
| 5 | resin | | | | temperature, | |
| | | | | | high humid | |
| Sample | Silicone | 10 | [MPa] | Acrylic | High | ∘ |
| 6 | gel | | | resin | temperature, | |
| | | | | | high humid | |
| Sample | — | 0 | [MPa] | Acrylic | High | ∘ |
| 7 | | | | resin | temperature, | |
| | | | | | high humid | |

The following findings were obtained from Table 1.

It was discovered from the evaluation results of samples 1 to 5 that firm anchoring of the sealing portion of the photoelectric conversion element leads to damage to the sealing structure of the photoelectric conversion element if the photoelectric conversion element module is exposed to a high temperature and high humidity condition. It can be estimated that firm anchoring of the sealing portion of the photoelectric conversion element makes it difficult for the covering section to absorb the stress caused by the moisture absorption and thermal expansion of the resin material, and as a result, a force is concentrated on the sealing portion of the photoelectric conversion element. On the other hand, no damage to the sealing structure of the photoelectric conversion element was confirmed from the evaluation result of sample 6 when silicone gel having a low Young's modulus was used as the covering section. That is, it was discovered that using a material having a low Young's modulus as the covering section makes it possible to avoid the concentration of a force on the sealing portion of the photoelectric conversion element. It can be estimated that the covering section has cushioned the stress caused by the moisture absorption and thermal expansion of the resin material. It should be noted that it was also discovered from the evaluation result of sample 7 that leaving the sealing portion of the photoelectric conversion element open can also avoid the concentration of a force on the sealing portion thereof.

As described above, the present technology provides a photoelectric conversion element module and architectural structure with minimal possible damage to the sealing structure of the dye sensitized solar cell.

The present disclosure contains subject matter related to that disclosed in Japanese Priority Patent Application JP 2011-159793 filed in the Japan Patent Office on Jul. 21, 2011, the entire content of which is hereby incorporated by reference.

What is claimed is:

1. A photoelectric conversion element module comprising:
a first base material;
a second base material;
a photoelectric conversion element having a light incident side and sealing portion and arranged between the first and second base materials;
an anchoring layer adapted to anchor one of main sides of a light incident side and a side opposite to the light incident side, and one of main sides of the first and second base material opposed to one of the main sides; and
a covering section adapted to cover the sealing portion, wherein
the Young's modulus of the covering section is 0 MPa or more and 20 MPa or less.

2. The photoelectric conversion element module of claim 1, wherein
the anchoring layer is formed on at least part of the light incident side or the main side opposite to the light incident side.

3. The photoelectric conversion element module of claim 2, wherein
the anchoring layer is formed in the form of a rib, or the anchoring layers are formed in the form of columns.

4. The photoelectric conversion element module of claim 1, wherein
the covering section is formed to have a height extending from the surface of the anchoring layer to the light incident side.

5. The photoelectric conversion element module of claim 1, wherein
the covering section is formed to have a height extending from the main side of the first and second base material opposed to one of the main sides to the light incident side.

6. The photoelectric conversion element module of claim 1, wherein
the covering section includes one or more selected from a group of silicone-based resin, modified silicone-based resin, urethane-based resin, polysulfide-based resin, modified polysulfide-based resin, telechelic polyacrylate-based resin, acrylic resin, acrylic urethane-based resin, vinyl acetate-based resin, acrylonitrile, hydrocarbon resin, alkylphenol resin, rosin-based resin, polyvinyl ether, synthetic rubber and natural rubber.

7. The photoelectric conversion element module of claim 1 further comprising:
a hollow layer between the light incident side and one of the first and second base materials.

8. The photoelectric conversion element module of claim 1, wherein
the light incident side is in close contact with one of the first and second base materials.

9. The photoelectric conversion element module of claim 1 further comprising:
a hollow layer between the main side opposite to the light incident side and one of the first and second base materials.

10. The photoelectric conversion element module of claim 1, wherein
the photoelectric conversion element includes
a transparent base material,
an opposed base material, and
a power generating element section, and
the sealing portion is provided between the peripheral portions of the transparent and opposed base materials.

11. The photoelectric conversion element module of claim 1, wherein
the photoelectric conversion element has a lateral side provided between the peripheral portions of the light incident side and the main side opposite to the light incident side, and
the sealing portion is provided on the peripheral portion of the light incident side, that of the main side opposite to the light incident side or the lateral side.

12. The photoelectric conversion element module of claim 1 further comprising:
a sealant provided between the peripheral portions of the first and second base materials.

13. The photoelectric conversion element module of claim 12 further comprising:
a shielding material provided between the peripheral portions of the first and second base materials.

14. The photoelectric conversion element module of claim 1, wherein
the first base material is a first glass plate, and
the second base material is a second glass plate.

15. The photoelectric conversion element module of claim 1, wherein
the anchoring layer contains one or more adhesives selected from a group of thermoplastic, thermosetting, room-temperature-setting and energy ray-setting adhesives.

16. The photoelectric conversion element module of claim 15, wherein
the energy ray-setting adhesive is an ultraviolet-setting adhesive.

17. An architectural structure comprising:
the photoelectric conversion element module including
a first base material,
a second base material,
a photoelectric conversion element having a light incident side and sealing portion and arranged between the first and second base materials,
an anchoring layer adapted to anchor one of main sides of a light incident side and a side opposite to the light incident side, and one of a main side of the first and second base material opposed to one of the main sides, and
a covering section adapted to cover the sealing portion, wherein
the Young's modulus of the covering section is 0 MPa or more and 20 MPa or less.
